(19) United States
(12) Patent Application Publication
(10) Pub. No.: US 2024/0210325 A1
(43) Pub. Date: Jun. 27, 2024

(54) Microcavity Plasma Array for Optical Emission Spectroscopy

(71) Applicant: Thermo Electron Scientific Instruments LLC, Madison, WI (US)

(72) Inventors: Patrick Lancuba, Fitchburg, WI (US); Sean Kellogg, Portland, OR (US)

(73) Assignee: Thermo Electron Scientific Instruments LLC, Madison, WI (US)

(21) Appl. No.: 18/086,395

(22) Filed: Dec. 21, 2022

(51) Int. Cl. G01N 21/71

(52) U.S. Cl. CPC G01N 21/718

(57) ABSTRACT

Disclosed herein are various systems and methods for optical emission spectroscopy. In some examples a substrate can be formed from conductive layers separated by a dielectric layer, the substrate having at least one recess therein, and the recess having a aperture therethrough. A chamber then encloses the area over the recess, the chamber including chamber walls, a gas inlet and a gas outlet to allow a gas to fill the chamber. An arc is then created across the substrate using the conductive layers. The arc may form a plasma using the gas inside the chamber. The plasma then ablates a surface of a specimen generating photons that can then be analyzed by a spectrometer.

### FIELD

The present disclosure generally relates to the field of optical emission spectroscopy and more specifically to systems and methods for employing micro arrays of test chambers.

### BACKGROUND

Spark-optical emission spectroscopy (spark-OES) is a type of chemical analysis test involves exposing a sample to an electrical spark that ionizes the test material. A spectrometer can then measure the different wavelengths of light that are emitted by the test material. Generally, spark-OES provides quantitative elemental analysis in a wide range of metallurgical sectors, including primary metal producers, foundries, car and aerospace manufacturing, and high-grade steels research. Spark-OES instruments perform analysis of major, minor, and trace elements by igniting a plasma between an electrode and the sample under consideration. This results in ablation of a portion of the specimen, followed by atomization and ionization. The subsequent light emission is then collected by a spectrometer. This technology is reliable, sturdy and well-suited for high-repetition chemical analysis.

While spark source technology has not significantly evolved since its first inception in the late 1930s, the industrial requirements did change. Today, the industry is under increasing pressure to dramatically improve performances such as, for example, 1) stability, 2) reproducibility, 3) inclusion analysis with imaging abilities, and 4) analysis of non-conductive samples. Accordingly, what is needed, is an arrangement that allows for quicker and more efficient ionization of a number of samples for optical emission analysis.

### SUMMARY

In a first aspect, an optical emission spectroscopy system may include: a substrate formed from conductive layers separated by a dielectric layer, the substrate having at least one recess therein, and the recess having a aperture therethrough; a chamber enclosing the recess, the chamber including chamber walls, a gas inlet and a gas outlet to allow a gas to fill the chamber; and a spectrometer sensitive to photons of a selected range of wavelengths; wherein, a plasma is generated in the aperture by placing a potential difference across the substrate using the conductive layers, the plasma ablating a surface of a specimen placed adjacent to the aperture opposite the recess, wherein the ablated material generates photons in an interaction with the plasma and the photons are analyzed by the spectrometer.

In a second aspect a micro-cavity array for use in an optical emission spectroscopy system may include: a non-conductive substrate comprising: a plurality of recesses etched into it, each recess having a aperture therethrough; a top conductive layer covering the non-conductive substrate, including each recess; and a bottom conductive layer covering an underside of the non-conductive layer; and a power source coupled to the top conductive layer and the bottom conductive layer, wherein the power source is configured to apply a voltage differential across the top conductive layer and the bottom conductive layer to generate a plasma.

In a third aspect, a method of operating an optical emission spectroscopy system may comprise: applying a potential across a top metal layer and a bottom metal layer, the top metal layer and bottom metal layer having a substrate therebetween, wherein the substrate is formed from a semiconductor layer having at least one recess therein, and the recess having a aperture therethrough; generating a plasma from a gas in a chamber enclosing the recess, the chamber including chamber walls, a gas inlet and a gas outlet to allow the gas to be moved through the chamber; and ablating a surface of a specimen placed adjacent to the aperture opposite the recess, wherein the ablated material generates photons in an interaction with the plasma and the photons are analyzed by a spectrometer.

### DRAWINGS

Examples will be readily understood by the following detailed description in conjunction with the accompanying drawings. To facilitate this description, like reference numerals designate like structural elements. Examples are illustrated by way of example, not by way of limitation, in the figures of the accompanying drawings.

FIGS. 1A and 1B provide block diagrams of exemplary optical emission spectroscopy systems, in accordance with various examples.

FIG. 2 provides a cross-sectional view of a microcavity structure comprising a substrate and conductors, in accordance with various examples.

FIG. 3A provides top view of a microcavity structure.

FIG. 3B provides top view of an alternative microcavity structure.

FIG. 4 provides a diagrammatic view of an optical emission spectroscopy system, in accordance with various examples.

FIG. 5 provides a flow diagram of an example method of photon generation, in accordance with various examples.

FIG. 6 provides is a block diagram of an example computing device that may perform some or all of the optical emission spectroscopy support methods disclosed herein, in accordance with various examples.

FIG. 7 provides a block diagram of an example optical emission spectroscopy support system in which some or all of the optical emission spectroscopy support methods disclosed herein may be performed, in accordance with various examples.

### DETAILED DESCRIPTION

Disclosed herein are optical emission systems, as well as related methods, computing devices, and computer-readable media. The section headings used herein are for organizational purposes only and are not to be construed as limiting the described subject matter in any way.

In this detailed description of the various examples, for purposes of explanation, numerous specific details are set forth to provide a thorough understanding of the examples disclosed. One skilled in the art will appreciate, however, that these various examples may be practiced with or without these specific details. In other instances, structures and devices are shown in block diagram form. Furthermore, one skilled in the art can readily appreciate that the specific sequences in which methods are presented and performed are illustrative and it is contemplated that the sequences can be varied and still remain within the spirit and scope of the various examples disclosed herein.

In the following detailed description, reference is made to the accompanying drawings that form a part hereof wherein like numerals designate like parts throughout, and in which is shown, by way of illustration, examples that may be practiced. It is to be understood that other examples may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the subject matter disclosed herein. However, the order of description should not be construed as to imply that these operations are necessarily order dependent. In particular, these operations may not be performed in the order of presentation. Operations described may be performed in a different order from the described example. Various additional operations may be performed, and/or described operations may be omitted in additional examples.

For the purposes of the present disclosure, the phrases “A and/or B” and “A or B” mean (A), (B), or (A and B). For the purposes of the present disclosure, the phrases “A, B, and/or C” and “A, B, or C” mean (A), (B), (C), (A and B), (A and C), (B and C), or (A, B, and C).

The description uses the phrases “an example,” “various examples,” and “some examples,” each of which may refer to one or more of the same or different examples. Furthermore, the terms “comprising,” “including,” “having,” and the like, as used with respect to examples of the present disclosure, are synonymous. When used to describe a range of dimensions, the phrase “between X and Y” represents a range that includes X and Y. As used herein, an “apparatus” may refer to any individual device or collection of devices. The drawings are not necessarily to scale.

### I. Optical Emission Spectrometry

Generally, Optical Emission Spectroscopy (OES) is a well trusted and widely used analytical technique used to determine the elemental composition of a broad range of metals. Currently, most OES systems can test samples including in primary and secondary metal production, and in the metals processing industries, tubes, bolts, rods, wires, plates and many more.

The majority of spark OES analyzers contain three major components: (1) an excitation generator like an electric spark or arc source; (2) an optical device that captures light and separates it into spectral lines; and (3) a detector that acquires the separated light and processes it based on predefined criteria/calibration metrics. Generally, the excitation generator creates a high voltage pulse that ionizes the atmosphere between the tip of the counter-electrode and the sample surface, causing it to become conductive. The gap between the electrode and sample becomes the lowest impedance, and thus a stable current may be generated. The generated current creates an electric spark or arc, which forms a plasma that heats the material to several thousand degrees. The material is then vaporized, atomized, and ionized.

Once the material is vaporized, atomized, and ionized, the optical device can capture any light emitted from the ionized sample material. The emitted light is then separated into its spectral lines and measured. By separating the light into spectral lines, the optical device can separate the incoming light into element-specific wavelengths. A corresponding detector may then measure the intensity of light for each wavelength, which are unique to each element, and determine, based on the measured intensity, the concentration of an element in the sample.

As should be understood by one of ordinary skill in the art, every element emits a series of spectral lines corresponding to the different electron transitions between the different energy levels or shells. Each transition produces a specific optical emission line with a fixed wavelength or energy of radiation. For example, for a typical metallic sample containing iron, manganese, chromium, nickel, vanadium, etc., each element may emit many wavelengths, leading to a line-rich spectrum (e.g., iron emits just over 8000 different wavelengths).

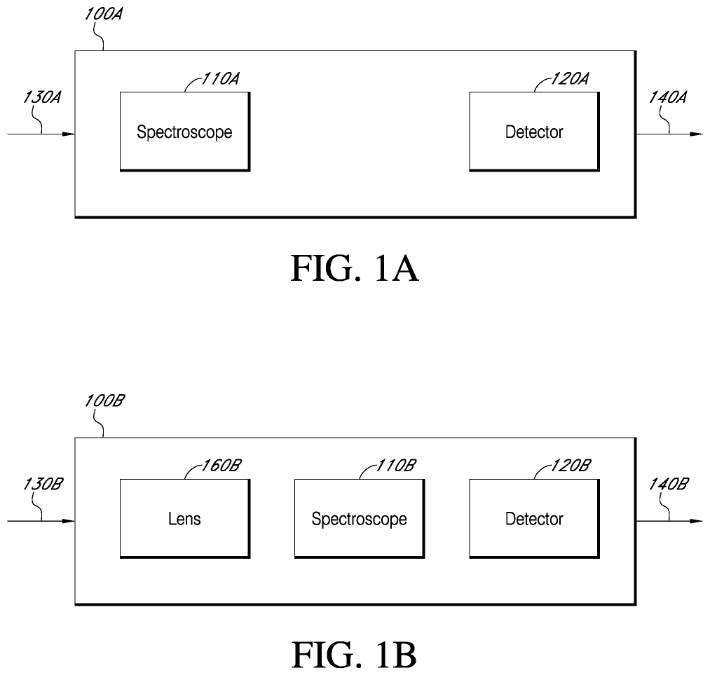

Generally, the peak wavelength identifies the element, and its peak area or intensity gives an indication of its quantity in the sample. The analyzer then uses this information to calculate the sample's elemental composition based on a calibration with certified reference material. Referring now to FIG. 1A, an OES device 100A is shown, which may, in some examples, include a spectroscope 110A and a detector 120A. The spectroscope 110A may decompose the optical emission 130A of a plasma generated according to the wavelength to detect and analyze the spectrum. In some example examples, the spectroscope 110A may include a grating or a prism, or the like. The grating may be a mirror having fine grooves and may include mechanical gratings having mechanically generated grooves and/or holographic gratings having grooves generated by patterning a photoresist and then etching the photoresist. In some examples, the wavelength resolution of the grating may be greater as the number of grooves increases.

In a further example, the detector 120A may generate optical emission spectroscopy (OES) data 140A by measuring an intensity of the optical emission 130A for each wavelength of the plasma from the detected spectrum. In some example examples, the detector 120A may be a charge-coupled device (CCD), or a photo diode array. The detector 120A may measure the intensity of the optical emission 130A based on an amount of charge generated by light.

Referring to FIG. 1B, an OES device 100B may include a spectroscope 110B, a detector 120B, and a lens (or lens assembly) 160B for providing parallel light into the spectroscope. In a further example, the lens 160B may include a focusing lens (not shown) and a collimator lens (not shown). In some examples, the focusing lens may form a point light source by focusing light incident on the OES device 100B. In another example, the collimator lens may convert the light emitted from the point light source into parallel light and transmit the converted light to the spectroscope 110B. In yet another example, when the spectroscope 110B is a grating, the lens 160B may include a telecentric lens. The telecentric lens may convert the light incident on the OES device 100B into parallel light and transmit the converted light to microgrooves of the spectroscope 110B.

Thus, as discussed above, OES technology has many advantages as well as many alternative methods of implementation. However, because of the popularity of Optical Emission Spectroscopy, the systems being designed today under increasing pressure to dramatically improve performances such as, for example: (1) stability; (2) reproducibility; (3) inclusion analysis with imaging abilities; and (4) analysis of non-conductive samples. The current Spark-OES technology is ill-suited to fulfil these requirements, because: (1) the sample spot size simply is too large (e.g., >5 mm) to allow micrometer-scale mapping; (2) it is not possible to control the exact location of each spark on the surface of the sample; and (3) Spark-OES only works with conductive samples. Accordingly, disclosed herein are systems and methods for performing OES using a microcavity plasma array.

### II. Microcavity Plasma Array OES

According to the concepts described herein, microcavity plasmas are small-volume DC discharge plasmas which typically operate at atmospheric pressure and have high plasma density and strong optical emission signals. Because these devices can be produced using micro-electromechanical systems (MEMS) technology, it is possible to form an array of cavities on a single device allowing plasma discharges along a planar surface. The array may be to amplify test signals from a sample, test at multiple surface locations on single test sample or to test multiple samples at the same time.

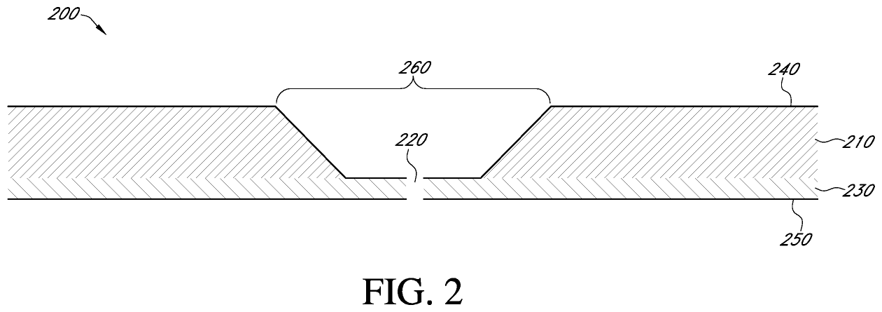

Referring now to FIG. 2, a cross-sectional view of a preferred example of a single microcavity structure 200 is shown. In certain examples, the microcavity structure 200 is preferably constructed as a metal-semiconductor-metal sandwich for ease of fabrication, but other structures may be employed where separated electrodes are able to produce a plasma in response to an applied voltage. In some examples, the microcavity structure 200 may be fabricated using a combination of MEMS processing technology and laser drilling, though any alternative manufacturing process may be used, provided it produces a functional microcavity plasma. For example, various examples may exist herein where the cavity shares the same essential design elements, which may include, but are not limited to, a first conducting electrode 240, a dielectric layer 210 (which may also include an oxide layer 230) and a second conducting electrode 250 having a aperture 220 therethrough.

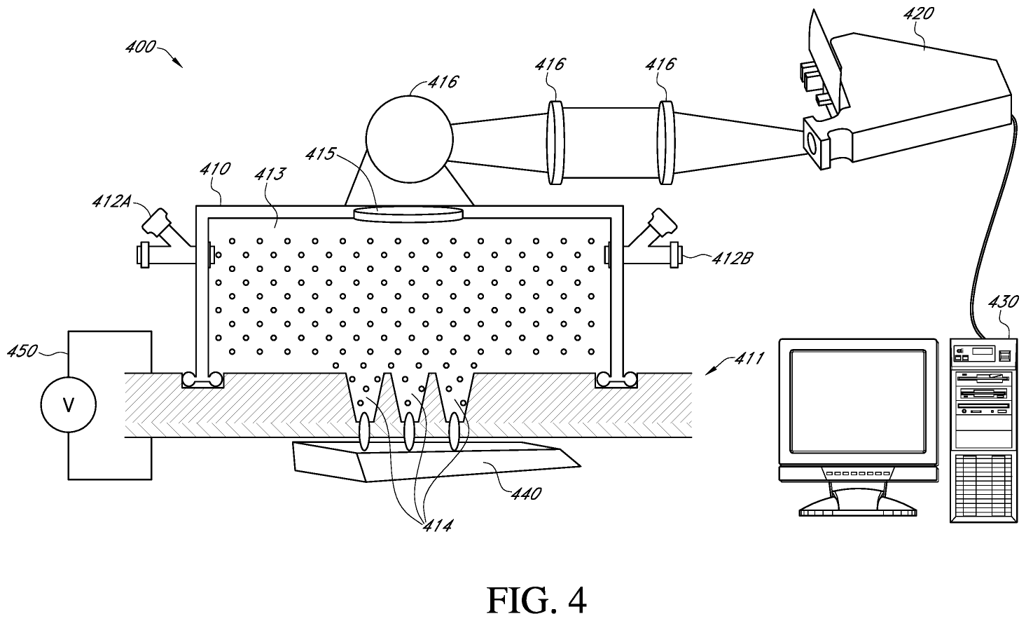

In some examples, the arrangement of the device is preferably planar so that the device can be laid upon a flat specimen (e.g., as shown in FIG. 4). In this example, the other substrate layer (e.g., 210 in FIG. 2) may not be necessary for the system to function. However, in alternative examples, it may be expedient to include the other substrate layer as a practicality for structural stability. This is because, in some examples, the dielectric layer 210 may have a very small optimal thickness (e.g., less than 1 mm), which could cause the device to lose rigidity or become fragile. Thus, as discussed herein, the device (e.g., material surrounding and/or creating the microcavity may be fabricated from a wide variety of materials provided that the outer layers are conductive, and the middle layer is insulating.

In some examples, and as shown, a silicon-on-insulator (SOI) wafer 210 may be etched (e.g., KOH etching, etc.) such that is has a recess 260 is created in the SOI wafer. The recess may take any of a variety of forms, including pyramidal, semi-spherical, round, oval, etc. In some examples, the etching may be performed in a single lithographic step, or, alternatively, in a sequence of individual steps. In some examples, the SOI wafer 210 is allowed to form a freestanding oxide layer 230 along one surface (e.g., SiO2). As should be understood by one of ordinary skill in the art, SiO2 (i.e., a native oxide) can form on the surface of a silicon wafer whenever the wafer is exposed to air under ambient conditions.

In a further example, a top metal layer 240 and a bottom metal layer 250 may be deposited on both sides of the microcavity structure 200. In some examples, the top and bottom metal layer 240/250 may be approximately 500-1000 nm thick. Due to the functional constraints of the system, making the either layer 240/250 to thin may cause it to have poor conductivity because the top metal layer 240 may be composed of discontinuous islands of metal deposition. Thus, in most examples, the top layer is preferably at least 100-200 nm thick. In a further example, if the lower layer 250 is too thin, it may reduce the plasma intensity at the specimen and thereby cause the performance of the spectroscopic application to suffer. Thus, in most examples, the bottom layer is preferably at least 10-20 μm thick. Alternatively, if the layers 240/250 are made too thick, the lower conductive layer 250 may cause the discharge to take place too far from the specimen (e.g., 440). Thus, so long as the plasma discharge is close enough to the specimen, the system should properly function. Common metals that can be deposited on the substrate include aluminum, nickel, chromium, gold, germanium, copper, silver, titanium, tungsten, platinum, tantalum or other metals and any of their alloys, that have the appropriate characteristics and conductivity.

Once the metal layers (e.g., 240 and 250) are deposited on the wafer 210, a portion of the metal may be removed (e.g., via a dicing saw, laser cutting, etc.) to create an aperture, e.g. hole, 220 aligned with the recess 260. In an additional or alternative example, the aperture 220 in the top and/or bottom metal layer 240/250 may be removed using the same or different methods. For example, the aperture 220 in the top layer 240 may be created by a saw or drill, while the aperture in the bottom layer 250 may be created using a laser cutter or laser drill.

Recess 260 is an optional structure, as only aperture 220 in wafer 210 and metal layers 240/250 are required for the formation of a plasma. The recess 260 may be used to control the thickness of the wafer 210 where the aperture is formed. In some instances, it may be desirable to use a wafer that is too thick for the sustainable formation of a plasma in the aperture 220. A recess 260, or recesses, may be formed in one or both sides to “thin” down the dielectric substrate wafer 210 to a thickness more suitable for plasma formation. After the formation of the recess/recesses the metal layers may be applied to both sides and the aperture 220 drilled therethrough. Ideal substrate thicknesses for the aperture formation may be between 0.005 mm and 2 mm.

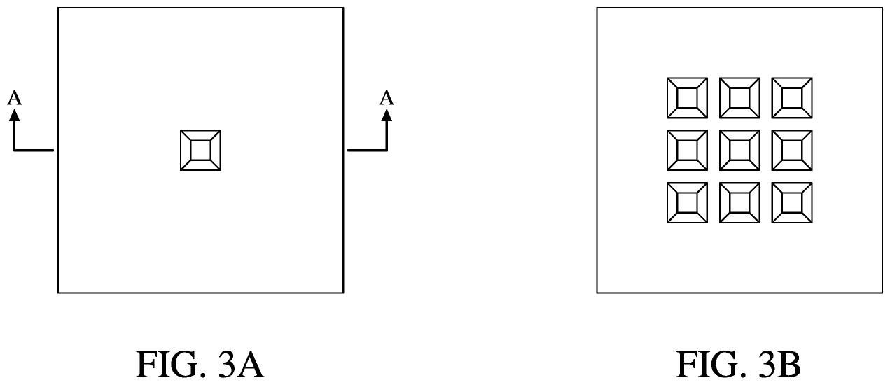

As stated above, the microcavity structure 200 shown in FIG. 2 has only a single recess 260 and one aperture 220. However, an array of recesses 260 and associated apertures 220 may be formed in a single substrate that may increase both the efficiency and accuracy of the OES system. The efficiency and accuracy may be increased by increasing the amount of ablated sample produced, by allowing sampling to occur at multiple points on the sample surface, or by allowing multiple samples to be tested simultaneously. Thus, as shown in contrasting FIGS. 3A and 3B, a plurality of structures or openings may be arranged on the microcavity structure 200 in an 1D array or 2D matrix. It should be understood that FIGS. 3A and 3B are illustrative examples only, and that the arrangement (e.g., 1D array or 2D matrix) of the aperture(s) 220 on the microcavity structure 200 may take may other forms, including, but not limited to different spacing, different shape, different number, etc.

It should be understood that although the recess 260 is shown a being primarily square (e.g., FIGS. 3A and 3B), it should be understood that various alternative examples may exist. By way of non-limiting example, the recess 260 of the microcavity structure may be of any configuration according to a chosen application, such as, for example, a square, a rectangle, a polygon, a circle, an ellipse, an oval, or other shape. In another example, the shape may be regular (i.e., all sides are equal in length and all interior angles measure the same) or irregular (i.e., having at least one side of unequal length and having at least one angle unequal to the others). Thus, it should be understood that the recess 260 may be symmetrical or non-symmetrical. The aperture(s) 220 at the bottom of the recess 260 may be between about 1 mm and 2 millimeters in diameter though apertures between about 0.5 mm and 5 mm are possible, as determined by the ability to produce and sustain a plasma when a voltage is applied. Too large or too small an aperture may prevent the formation or sustainment of the desired plasma. The aperture may be square, round or other configuration as determined by the application or manufacturing technique. In certain examples, recess 260 may be omitted, relying instead only on aperture 220. However, the inclusion of a recess is advantageous due to the crystal faces that appear when you etch silicon with potassium hydroxide, and thus, for such etching, it may be convenient to include a recess as disclosed herein.

Referring now to FIG. 4, an illustrative example of an optical emission spectroscopy system 400 is shown. In some examples, and as shown, the OES system may include a chamber 410. In some examples, the chamber 410 may have one or more walls enclosing a volume 413. The walls of the chamber may create an airtight or mostly airtight seal against the microcavity structure 411, such as shown and described in FIG. 2.

In preferred examples, the OES system 400 may have one or more connections (e.g., valves, openings, inlets, outlets, etc.) 412A and 412B that allow for control of the ambient air in the volume 413 within the chamber 410. For example, in some examples, the connections 412A/412B may be connected to a vacuum pump/system which removes all the gasses from the chamber 410 chamber, thereby creating a near vacuum. In an additional or alternative example, the connections 412A/412B may be used to add particular gasses to the chamber 410. Thus, in some examples, the system may first create a vacuum within the chamber 410, and then insert a specific gas type such as, for example, argon, xenon, nitrogen, or the like. In a further example, the system may use valves and/or control circuits to automatically control the removal and insertion of gas from the chamber 410. In certain preferred examples, volume 413 in chamber 410 is evacuated and then filled with a gas, such as argon, which is used to facilitate the creation of a plasma in aperture/recess structures 414.

Once the volume 413 inside the chamber 410 has the desired type and pressure of gas, the OES system 400 can begin creating plasmas in the aperture/recess structures 414. In some examples, and as shown, a voltage power source 450 may apply a voltage to the top and/or bottom conductor layers (e.g., 240 and 250) to create a voltage difference (e.g., between 1 V and 1000 V) between the two layers. The applied voltage potential between the two conductive layers 240/250 is enough to ignite and sustain a plasma discharge in the aperture and surrounding conductive layers. As should be understood by one of ordinary skill in the art, a plasma discharge is an electrical breakdown of a gas, such as argon, which partially ionizes the gas, releasing light and heat as the current flows through the discharge.

The plasma discharge formed in the aperture of aperture/recess structure 414 is energetic enough to ablate the surface of sample 440 releasing some of the sample into the recess and chamber 410. The plasma heats the released sample and ionizes the material, which then releases electromagnetic radiation/photons at wavelengths specific to the material as previously described. These photons can then be captured by a spectrometer and analyzed to determine the composition of the sample.

The plasma discharge created may be monitored by the OES system 400 to ensure it is the desired size and has the desired duration to ablate the sample 440 and release the desired material into the chamber 410. In some examples, the OES system may have photosensitive receptors 418 that can view the microcavity through a window 415. The window may be constructed of any suitable material to maintain the integrity of the chamber 410, while also allowing for an accurate view of the microcavity structure 411 and the aperture/recess structures 414 located thereupon. In other examples, the OES system may comprise a plurality of windows to allow for redundant view or views from alternative angles or the chamber walls may be transparent to allow for the transmission of photons through the walls.

In some examples, the window 415 allows the photons to pass out of chamber 410 to photo receptors 418. A focusing lens or lenses 416 may be used by the OES system 400 to better direct and/or focus the optical emission onto photo receptors 418. In a further example, the OES system 400 may include multiple focusing or refracting lenses 416, which may be used to improve the quality of the image data captured by the photo receptors 418. Photo receptors 418 are part of a spectrometer which takes the data from the photoreceptors and analyzes it to determine spectral wavelengths and peaks.

In some examples, the area of interest of the specimen may be smaller than 20×20 mm. In this example, a fixed lens would likely be sufficient for viewing/capturing the entire area. However, in some examples, the area of interest may be larger than a typical area (e.g., greater than 20 mm×20 mm). When the area of interest is larger, an example, may use a fixed f-theta lens combined with a Galvanometer (Galvo), which is an electromechanical instrument that deflects a light beam, to convey light from a flat surface into the spectrometer.

As discussed herein, the microcavity structure 411 in OES system 400 may have one recess 260 and one aperture 220, or multiple. Thus, in some examples, the chamber 410 may enclose a single recess 260 and single aperture 220, or multiple 414, as shown. In an additional or alternative example, the microcavity structure 411 may have multiple apertures/recesses 414, in which each aperture/recess has its own chamber. Stated differently, a microcavity chamber may contain an array (e.g., a 2D matrix as shown in FIG. 3B) of apertures/recesses 414, or in alternative examples a microcavity chamber 410 may enclose a single aperture/recess 414 and may include an array of chambers 410, each enclosing a single aperture/recess.

Thus, it should be understood that any arrangement of apertures/recesses 414 to chambers 410 may exist. For example, in an example where the microcavity structure 411 has 100 apertures/recesses 414, any number of chambers from 1 to 100 may be used (e.g., 50 apertures/recesses per chamber, 25 apertures/recesses per chamber, 10 apertures/recesses per chamber, 5 apertures/recesses per chamber, 1 apertures/recesses per chamber etc.). It should also be understood that the apertures/recesses to chamber ration does not have to be consistent, thus on a single microcavity structure 411, one chamber 410 may enclose 10 apertures/recesses 414, while another encloses 5, and yet another encloses 50.

Regardless of the arrangement and/or number of apertures/recesses 414, the OES system 400 may, in some examples, operate each individual plasma discharge structure (e.g., the discharge at a particular aperture/recess) can be operated independently of the others. By way of a non-limiting example, the OES system 400 may provide separate voltage control to each aperture/recess 414 rather than to the entire array of apertures, provided that the electrodes terminating each microcavity are individually addressable (e.g., using a multiplexing system, like the addressable pixels in a plasma display panel). Accordingly, in some examples, it may be possible to scan the specimen 440 by sequentially operating the apertures/recesses 414 (e.g., to create the plasma discharges) one after another (e.g., without moving the discharge array over the specimen).

It should be further understood that the arrangement of apertures/recesses 414 may be grouped, or divided, into sub-parts (e.g., a microcavity 411 structure with 200 apertures/recesses may comprise 2, 4, 8, etc. sub-parts, each sub-part comprising 100, 50, or 25 apertures/recesses respectively). Thus, in some examples, the OES system 400 may operate a sub-part, or sub-group, of the apertures/recesses 414 instead of each aperture/recess individually. Furthermore, it should be understood that, in some examples, the number of apertures/recesses 414 included in each sub-part may not be equal. By way of non-limiting example, one sub-part may include 10 apertures/recesses 414, while another has 5, 20, 30, 40, 50, or more, including fractions or interpolation thereof.

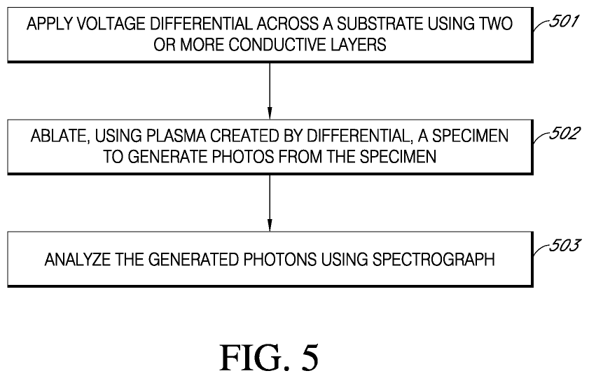

Referring now to FIG. 5, as discussed herein, the OES system 400 can generate a plasma by placing a potential difference across a substrate (e.g., 210) using two or more conductive layers (e.g., 240 and 250) 501. The plasma ablates a surface of a specimen 440 placed below or adjacent to the aperture. Ablation of the surface of the specimen 440 can then generate photons 502 through the interaction of the specimen material with the plasma. The photons are then captured and analyzed 503 by a spectrometer 420. In some examples, the spectrometer 420 may be connected to a local or remote computing device 430 that has software designed to analyze and process spectrometer data.

### III. Data Processing Platform

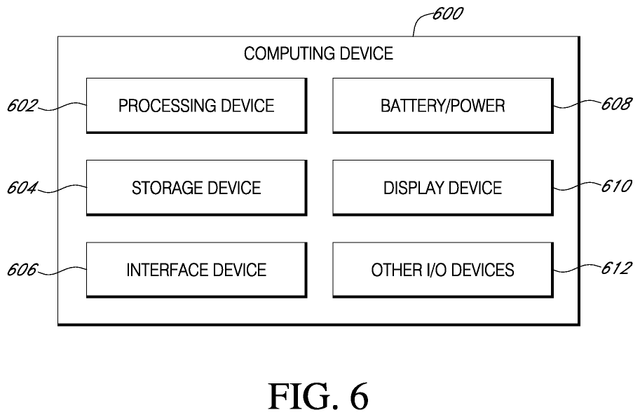

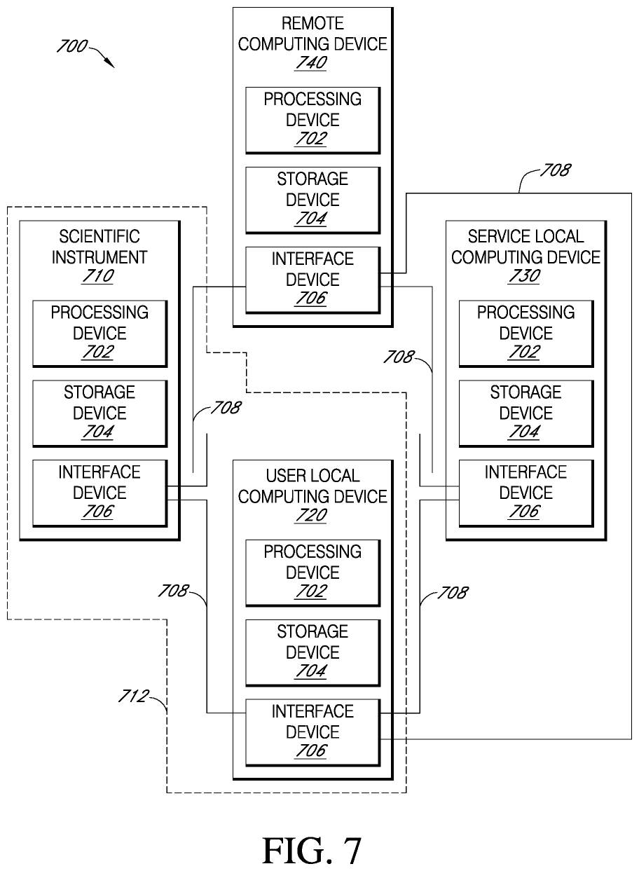

As noted above, the OES platform 400 may be implemented by one or more computing devices. FIG. 6 is a block diagram of a computing device 600 that may perform some or all of the OES support methods disclosed herein, in accordance with various examples. In some examples, the OES system 400 may be implemented by a single computing device 600 or by multiple computing devices 600. Further, as discussed below, a computing device 600 (or multiple computing devices 600) that implements the OES system 400 may be part of one or more of the scientific instruments 710, the user local computing device 720, the service local computing device 730, or the remote computing device 740 of FIG. 7.

The computing device 600 of FIG. 6 is illustrated as having a number of components, but any one or more of these components may be omitted or duplicated, as suitable for the application and setting. In some examples, some or all of the components included in the computing device 600 may be attached to one or more motherboards and enclosed in a housing (e.g., including plastic, metal, and/or other materials). In some examples, some these components may be fabricated onto a single system-on-a-chip (SoC) (e.g., an SoC may include one or more processing devices 602 and one or more storage devices 604). Additionally, in various examples, the computing device 600 may not include one or more of the components illustrated in FIG. 6, but may include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 600 may not include a display device 610, but may include display device interface circuitry (e.g., a connector and driver circuitry) to which a display device 610 may be coupled.

The computing device 600 may include a processing device 602 (e.g., one or more processing devices). As used herein, the term “processing device” may refer to any device or portion of a device that processes electronic data from registers and/or memory to transform that electronic data into other electronic data that may be stored in registers and/or memory. The processing device 602 may include one or more digital signal processors (DSPs), application-specific integrated circuits (ASICs), central processing units (CPUs), graphics processing units (GPUs), crypto-processors (specialized processors that execute cryptographic algorithms within hardware), server processors, or any other suitable processing devices.

The computing device 600 may include a storage device 604 (e.g., one or more storage devices). The storage device 604 may include one or more memory devices such as random-access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some examples, the storage device 604 may include memory that shares a die with a processing device 602. In such an example, the memory may be used as cache memory and may include embedded dynamic random-access memory (eDRAM) or spin transfer torque magnetic random-access memory (STT-MRAM), for example. In some examples, the storage device 604 may include non-transitory computer readable media having instructions thereon that, when executed by one or more processing devices (e.g., the processing device 602), cause the computing device 600 to perform any appropriate ones of or portions of the methods disclosed herein.

The computing device 600 may include an interface device 606 (e.g., one or more interface devices 606). The interface device 606 may include one or more communication chips, connectors, and/or other hardware and software to govern communications between the computing device 600 and other computing devices. For example, the interface device 606 may include circuitry for managing wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not. Circuitry included in the interface device 606 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). In some examples, circuitry included in the interface device 606 for managing wireless communications may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some examples, circuitry included in the interface device 606 for managing wireless communications may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some examples, circuitry included in the interface device 606 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some examples, the interface device 606 may include one or more antennas (e.g., one or more antenna arrays) to receipt and/or transmission of wireless communications.

In some examples, the interface device 606 may include circuitry for managing wired communications, such as electrical, optical, or any other suitable communication protocols. For example, the interface device 606 may include circuitry to support communications in accordance with Ethernet technologies. In some examples, the interface device 606 may support both wireless and wired communication, and/or may support multiple wired communication protocols and/or multiple wireless communication protocols. For example, a first set of circuitry of the interface device 606 may be dedicated to shorter-range wireless communications such as Wi-Fi or Bluetooth, and a second set of circuitry of the interface device 606 may be dedicated to longer-range wireless communications such as global positioning system (GPS), EDGE, GPRS, CDMA, WiMAX, LTE, EV-DO, or others. In some examples, a first set of circuitry of the interface device 606 may be dedicated to wireless communications, and a second set of circuitry of the interface device 606 may be dedicated to wired communications.

The computing device 600 may include battery/power circuitry 608. The battery/power circuitry 608 may include one or more energy storage devices (e.g., batteries or capacitors) and/or circuitry for coupling components of the computing device 600 to an energy source separate from the computing device 600 (e.g., AC line power).

The computing device 600 may include a display device 610 (e.g., multiple display devices). The display device 610 may include any visual indicators, such as a heads-up display, a computer monitor, a projector, a touchscreen display, a liquid crystal display (LCD), a light-emitting diode display, or a flat panel display.

The computing device 600 may include other input/output (I/O) devices 612. The other I/O devices 612 may include one or more audio output devices (e.g., speakers, headsets, earbuds, alarms, etc.), one or more audio input devices (e.g., microphones or microphone arrays), location devices (e.g., GPS devices in communication with a satellite-based system to receive a location of the computing device 600, as known in the art), audio codecs, video codecs, printers, sensors (e.g., thermocouples or other temperature sensors, humidity sensors, pressure sensors, vibration sensors, accelerometers, gyroscopes, etc.), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 600 may have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra-mobile personal computer, etc.), a desktop computing device, or a server computing device or other networked computing component.

One or more computing devices implementing any of the optical emission spectroscopy support modules or methods disclosed herein may be part of an optical emission spectroscopy support system. FIG. 7 is a block diagram of an example OES support system 700 in which some or all of the optical emission spectroscopy support methods disclosed herein may be performed, in accordance with various examples. The optical emission spectroscopy support modules and methods disclosed herein (e.g., the optical emission spectroscopy system 400 of FIG. 4 and the method 500 of FIG. 5) may be implemented by one or more of the scientific instruments 710, the user local computing device 720, the service local computing device 730, or the remote computing device 740 of the OES support system 700.

Any of the scientific instrument 710, the user local computing device 720, the service local computing device 730, or the remote computing device 740 may include any of the examples of the computing device 600 discussed herein with reference to FIG. 6, and any of the scientific instrument 710, the user local computing device 720, the service local computing device 730, or the remote computing device 740 may take the form of any appropriate ones of the examples of the computing device 600 discussed herein with reference to FIG. 6.

The scientific instrument 710, the user local computing device 720, the service local computing device 730, or the remote computing device 740 may each include a processing device 702, a storage device 704, and an interface device 706. The processing device 702 may take any suitable form, including the form of any of the processing devices 602 discussed herein with reference to FIG. 6, and the processing devices 702 included in different ones of the scientific instrument 710, the user local computing device 720, the service local computing device 730, or the remote computing device 740 may take the same form or different forms. The storage device 704 may take any suitable form, including the form of any of the storage devices 604 discussed herein with reference to FIG. 6, and the storage devices 704 included in different ones of the scientific instrument 710, the user local computing device 720, the service local computing device 730, or the remote computing device 740 may take the same form or different forms. The interface device 706 may take any suitable form, including the form of any of the interface devices 606 discussed herein with reference to FIG. 6, and the interface devices 706 included in different ones of the scientific instrument 710, the user local computing device 720, the service local computing device 730, or the remote computing device 740 may take the same form or different forms.

The scientific instrument 710, the user local computing device 720, the service local computing device 730, and the remote computing device 740 may be in communication with other elements of the OES support system 700 via communication pathways 708. The communication pathways 708 may communicatively couple the interface devices 706 of different ones of the elements of the OES support system 700, as shown, and may be wired or wireless communication pathways (e.g., in accordance with any of the communication techniques discussed herein with reference to the interface devices 606 of the computing device 600 of FIG. 6). The particular OES support system 700 depicted in FIG. 7 includes communication pathways between each pair of the scientific instrument 710, the user local computing device 720, the service local computing device 730, and the remote computing device 740, but this “fully connected” implementation is simply illustrative, and in various examples, various ones of the communication pathways 708 may be absent. For example, in some examples, a service local computing device 730 may not have a direct communication pathway 708 between its interface device 706 and the interface device 706 of the scientific instrument 710, but may instead communicate with the scientific instrument 710 via the communication pathway 708 between the service local computing device 730 and the user local computing device 720 and the communication pathway 708 between the user local computing device 720 and the scientific instrument 710.

The user local computing device 720 may be a computing device (e.g., in accordance with any of the examples of the computing device 600 discussed herein) that is local to a user of the scientific instrument 710. In some examples, the user local computing device 720 may also be local to the scientific instrument 710, but this need not be the case; for example, a user local computing device 720 that is in a user's home or office may be remote from, but in communication with, the scientific instrument 710 so that the user may use the user local computing device 720 to control and/or access data from the scientific instrument 710. In some examples, the user local computing device 720 may be a laptop, smartphone, or tablet device. In some examples the user local computing device 720 may be a portable computing device.

The service local computing device 730 may be a computing device (e.g., in accordance with any of the examples of the computing device 600 discussed herein) that is local to an entity that services the scientific instrument 710. For example, the service local computing device 730 may be local to a manufacturer of the scientific instrument 710 or to a third-party service company. In some examples, the service local computing device 730 may communicate with the scientific instrument 710, the user local computing device 720, and/or the remote computing device 740 (e.g., via a direct communication pathway 708 or via multiple “indirect” communication pathways 708, as discussed above) to receive data regarding the operation of the scientific instrument 710, the user local computing device 720, and/or the remote computing device 740 (e.g., the results of self-tests of the scientific instrument 710, calibration coefficients used by the scientific instrument 710, the measurements of sensors associated with the scientific instrument 710, etc.). In some examples, the service local computing device 730 may communicate with the scientific instrument 710, the user local computing device 720, and/or the remote computing device 740 (e.g., via a direct communication pathway 708 or via multiple “indirect” communication pathways 708, as discussed above) to transmit data to the scientific instrument 710, the user local computing device 720, and/or the remote computing device 740 (e.g., to update programmed instructions, such as firmware, in the scientific instrument 710, to initiate the performance of test or calibration sequences in the scientific instrument 710, to update programmed instructions, such as software, in the user local computing device 720 or the remote computing device 740, etc.). A user of the scientific instrument 710 may utilize the scientific instrument 710 or the user local computing device 720 to communicate with the service local computing device 730 to report a problem with the scientific instrument 710 or the user local computing device 720, to request a visit from a technician to improve the operation of the scientific instrument 710, to order consumables or replacement parts associated with the scientific instrument 710, or for other purposes.

The remote computing device 740 may be a computing device (e.g., in accordance with any of the examples of the computing device 600 discussed herein) that is remote from the scientific instrument 710 and/or from the user local computing device 720. In some examples, the remote computing device 740 may be included in a datacenter or other large-scale server environment. In some examples, the remote computing device 740 may include network-attached storage (e.g., as part of the storage device 704). The remote computing device 740 may store data generated by the scientific instrument 710, perform analyses of the data generated by the scientific instrument 710 (e.g., in accordance with programmed instructions), facilitate communication between the user local computing device 720 and the scientific instrument 710, and/or facilitate communication between the service local computing device 730 and the scientific instrument 710.

In some examples, one or more of the elements of the OES support system 700 illustrated in FIG. 7 may not be present. Further, in some examples, multiple ones of various ones of the elements of the OES support system 700 of FIG. 7 may be present. For example, an OES support system 700 may include multiple user local computing devices 720 (e.g., different user local computing devices 720 associated with different users or in different locations). In another example, an OES support system 700 may include multiple scientific instruments 710, all in communication with service local computing device 730 and/or a remote computing device 740; in such an example, the service local computing device 730 may monitor these multiple scientific instruments 710, and the service local computing device 730 may cause updates or other information may be “broadcast” to multiple scientific instruments 710 at the same time. Different ones of the scientific instruments 710 in an OES support system 700 may be located close to one another (e.g., in the same room) or farther from one another (e.g., on different floors of a building, in different buildings, in different cities, etc.). In some examples, a scientific instrument 710 may be connected to an Internet-of-Things (IoT) stack that allows for command and control of the scientific instrument 710 through a web-based application, a virtual or augmented reality application, a mobile application, and/or a desktop application. Any of these applications may be accessed by a user operating the user local computing device 720 in communication with the scientific instrument 710 by the intervening remote computing device 740. In some examples, a scientific instrument 710 may be sold by the manufacturer along with one or more associated user local computing devices 720 as part of a local scientific instrument computing unit 712.

In some examples, different ones of the scientific instruments 710 included in an OES support system 700 may be different types of scientific instruments 710. In some such examples, the remote computing device 740 and/or the user local computing device 720 may combine data from different types of scientific instruments 710 included in an OES support system 700.

What is claimed is:

1. An optical emission spectroscopy system, comprising:
a substrate formed from conductive layers separated by a dielectric layer, the substrate having at least one aperture therethrough;
a chamber enclosing the at least one aperture, the chamber including chamber walls, a gas inlet and a gas outlet to allow a gas to fill the chamber; and
a spectrometer, optically coupled with the chamber and sensitive to photons of a selected range of wavelengths;
wherein, a plasma is generated in or near the aperture by placing a potential difference across the substrate using the conductive layers, the plasma ablating a surface of a specimen placed adjacent to the aperture, wherein material ablated from the specimen generates photons in an interaction with the plasma and the photons are received and analyzed at the spectrometer.

2. The system of claim 1 wherein the aperture is between 1 micrometer and 2 millimeters in diameter.

3. The system of claim 1 wherein the aperture is shaped like at least one of, a square, a rectangle, a polygon, a circle, an ellipse, an oval, non-symmetrical polygon, or a symmetrical polygon.

4. The system of claim 1 wherein the dielectric layer of the substrate is a silicon dioxide layer of a silicon wafer and the conductive layers are formed from a metal or metal alloy.

5. The system of claim 4, wherein a recess is formed through a first conductive layer of the conductive layers and in the dielectric layer, the recess having a pyramidal shape, and wherein the aperture is formed through the remaining dielectric layer and a second conductive layer of the conductive layers.

6. The system of claim 5 wherein the recess is formed by etching the substrate and the aperture is formed by laser drilling.

7. The system of claim 5 wherein an array of recesses is formed on the substrate, each recess with an associated aperture.

8. The system of claim 1 wherein the gas is at least one of argon, xenon, or nitrogen.

9. The system of claim 1 wherein the potential difference is between 1 and 1000 volts.

10. The system of claim 1 wherein at least one of the chamber walls comprises an optically transmissive region allowing the photons to exit the chamber.

11. A micro-cavity array for use in an optical emission spectroscopy system, the micro-cavity array comprising:
a substrate formed of first and second conductive layers disposed on opposing sides of a non-conductive layer;
a plurality of apertures formed through the substrate; and
a power source coupled with the top conductive layer and the bottom conductive layer, wherein the power source is configured to apply a voltage differential across the top conductive layer and the bottom conductive layer to generate a plasma in an associated aperture.

12. The micro-cavity array of claim 11 further comprising a plurality of recesses formed into the substrate, wherein each of the plurality of recesses are arranged to encompass an associated aperture of the plurality of apertures.

13. The micro-cavity array of claim 11 wherein each aperture is between 1 micrometer and 2 millimeters in diameter.

14. The micro-cavity array of claim 11 wherein the plasma ablates a portion of a specimen placed adjacent to at least one aperture of the plurality of apertures.

15. The micro-cavity array of claim 14 wherein the ablation of the portion of the specimen emits photons in response to an interaction with the plasma, the photons passing through an optical region of a sealed container and interacting with a spectrometer.

16. The micro-cavity array of claim 11 wherein at least one aperture of the plurality of apertures is shaped like at least one of, a square, a rectangle, a polygon, a circle, an ellipse, an oval, non-symmetrical polygon, or a symmetrical polygon.

17. A method of operating an optical emission spectroscopy system, the method comprising:
applying a potential across a top metal layer and a bottom metal layer, the top metal layer and bottom metal layer having a substrate therebetween, wherein the substrate is formed from a semiconductor layer having a plurality of apertures therethrough, each aperture located in a recess in the substrate;
generating a plasma from a gas in a chamber enclosing one or more of the plurality of apertures, the chamber including chamber walls, a gas inlet and a gas outlet to allow the gas to be moved through the chamber; and
ablating a surface of a specimen placed adjacent to the one or more of the plurality of apertures, wherein material ablated from the specimen generates photons in an interaction with the plasma and the photons are analyzed by a spectrometer.

18. The method of claim 17 further comprising analyzing the photons to determine a composition of the specimen.

19. The method of claim 17 wherein the gas is at least one of argon, xenon, or nitrogen.

20. The method of claim 17 wherein each of the plurality of apertures is between 1 micrometer and 2 millimeters in diameter.

21. The method of claim 17 wherein each recess is formed by etching the substrate and wherein each of the plurality of apertures is formed by laser drilling within the recess.
